(19) United States
(12) Patent Application Publication
(10) Pub. No.: US 2018/0076160 A1
(43) Pub. Date: Mar. 15, 2018

(54) MASKLESS SELECTIVE RETENTION OF A CAP UPON A CONDUCTOR FROM A NONCONDUCTIVE CAPPING LAYER

(71) Applicant: International Business Machines Corporation, Armonk, NY (US)

(72) Inventors: Brian M. Erwin, Lagrangeville, NY (US); Brittany L. Hedrick, Wappingers Falls, NY (US); Nicholas A. Polomoff, White Plains, NY (US); TaeHo Kim, Hwaseong (KR); Matthew E. Souter, Tustin, CA (US)

(73) Assignee: SUSS MicroTec Photonic Systems Inc., Corona, CA (US)

(21) Appl. No.: 15/813,311

(22) Filed: Nov. 15, 2017

Related U.S. Application Data
(62) Division of application No. 14/920,197, filed on Oct. 22, 2015.

(51) Int. Cl. H01L 23/00

(52) U.S. Cl. CPC H01L 24/11; H01L 2224/0381; H01L 2224/03632; H01L 2224/0382; H01L 2224/1181; H01L 2224/11632; H01L 2924/05042; H01L 2224/1182; H01L 2224/13147; H01L 2224/12105; H01L 2224/04105; H01L 24/13; H01L 24/05; H01L 24/03

(57) ABSTRACT

A semiconductor structure includes an electrically conductive structure formed upon an uppermost organic layer of a semiconductor substrate. A capping layer is formed upon the uppermost organic layer covering the electrically conductive structure. A maskless selective removal lasering technique ejects portions of the capping layer while retaining the portion of the capping layer covering the electrically conductive structure. Portions of the capping layer are ejected from the uppermost organic layer by a shockwave as a result of the laser beam vaporizing the uppermost organic layer of the semiconductor substrate. Portions of the capping layer contacting the electrically conductive structure are retained by the conductive structure dissipating heat from the laser that would otherwise vaporize the uppermost organic layer of the semiconductor substrate.

### FIELD

Embodiments of invention generally relate to semiconductor devices and semiconductor device fabrication methods. More particularly, embodiments relate to forming and retaining a cap upon a conductive structure (e.g. pillar, pad, wire, etc.) from a nonconductive capping layer utilizing a maskless selective removal technique.

### BACKGROUND

A semiconductor chip is fabricated upon a wafer and includes numerous conductive contact structures such as conductive contacts, pillars, pads utilized to electrically connect the chip to another semiconductor package, such as a second chip, carrier, etc. The semiconductor chip also includes numerous conductive connection structures such as metal wires that are utilized to electrically connect one or more conductive contacts to other structures included within the semiconductor chip. In numerous instances it may be advantageous to cap such conductive structures with a nonconductive cap. For example, a cap, formed from a conformal coating layer, may cover each of the numerous conductive contact structures.

Conventionally, undesired conformal coating layer material is removed from wafers or substrates using either a wet, dry or plasma etch process. However, there are a number of drawbacks associated with these conventional processes, in that they become “process-limited” as the requirement for finer pitch structures and yields are required, and the process times and methods involved can constitute a higher cost of ownership in applications in which this consideration is highly sensitive. Additionally, some of the conventional processes are environmentally unfriendly.

For example, in the case of the wet etching process, wet etching is not selective. Thus, all conformal coating material will be removed unless portions of the conformal coating material are protected by a mask. As semiconductor chips become smaller by design, the effectiveness of wet etching becomes increasingly limited, because the same amount of etching occurs on the circuitry patterns which the manufacturer wants to leave behind as occurs on the unwanted conformal coating layer. This adversely affects product reliability and limits feature dimensions, e.g., the pitch, of the circuitry being left behind. As will be appreciated, when the pitch between relatively high-aspect-ratio features decreases, this also increases the difficulty in removing the conformal coating material by means of the wet etch process. This, in turn, provides constraints on chip design and limits the spacing that can be used between the conductive contact structures.

Additionally, as will be appreciated, the wet etch process uses harsh chemicals that etch away the metal seed layer. However, the process steps prior to the etching step involve applying various materials to the conformal coating, residual amounts of which can be left behind as residues. These residues, which can be several nanometers thick, act as contaminates on the conformal coating layer that “mask” the wet etch process, causing incomplete removal of the conformal coating layer.

Further, the wet etch process requires relatively large amounts of chemicals to etch away the conformal coating. In addition, these same etch chemicals also tend to leach into the underlying material, with a resultant negative yield affect. The by-product of the chemical etch process is a hazardous waste that requires costly hazardous waste disposal methods. The precious metals that are removed are saturated into the chemical etchant and are disposed of along with the chemical etchant. With the worldwide concentration on so-called “Green” initiatives, use and disposal of these chemicals are deemed highly undesirable.

Other conventional removal techniques such as plasma etching processes entail similar drawbacks, to which are added the higher costs typically associated with the equipment needed to produce and control the plasma etch.

### SUMMARY

In an embodiment of the present invention, a method to form a cap upon a semiconductor chip to package interconnect contact structure includes forming a contact structure upon an uppermost organic layer of a semiconductor substrate, forming a capping layer upon the uppermost organic layer covering the contact structure, and directing a laser beam through the capping layer to the uppermost organic layer to eject portions of the capping layer from the uppermost organic layer while retaining the capping layer covering the contact structure.

These and other embodiments, features, aspects, and advantages will become better understood with reference to the following description, appended claims, and accompanying drawings.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1A depicts an isometric view of an exemplary semiconductor wafer that may include one or more embodiments of the present invention.

FIG. 1B depicts a cross section of an exemplary semiconductor wafer that may include one or more embodiments of the present invention.

FIG. 2-FIG. 5 depicts fabrication process stages to form a cap upon a contact structure utilizing a maskless selective removal technique to remove portions of a capping layer, according to embodiments of the invention.

FIG. 6-FIG. 9 depicts fabrication process stages to form a cap upon a contact structure utilizing a maskless selective removal technique to remove portions of a capping layer, according to embodiments of the invention.

FIG. 10 and FIG. 11 depict exemplary semiconductor device fabrication flow methods, according to embodiments of the invention.

FIG. 12 depicts a semiconductor device including a capped contract structure, according to embodiments of the invention.

FIG. 13 depicts a semiconductor chip-to-package interconnect, according to embodiments of the invention.

FIG. 14A depicts a top view of an exemplary semiconductor wafer that may include one or more embodiments of the present invention.

FIG. 14B depicts a cross section of an exemplary semiconductor wafer that may include one or more embodiments of the present invention.

The drawings are not necessarily to scale. The drawings are merely schematic representations, not intended to portray specific parameters of the invention. The drawings are intended to depict only exemplary embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures or methods that may be embodied in various forms. These exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

Embodiments relate to a semiconductor structure which includes a conductive structure formed upon an uppermost organic layer of a semiconductor substrate. A capping layer is formed upon an uppermost organic layer of a substrate covering the conductive structure. A maskless selective removal lasering technique ejects portions of the capping layer while retaining the portion of the capping layer covering the conductive structure. The capping layer is ejected at its interface with the uppermost organic layer of the substrate. The uppermost organic layer of the substrate surface is vaporized by the laser resulting in a shockwave which ejects the capping layer. The capping layer over the conductive structure remains in place because the surface of the conductive structure is not vaporized by the laser. The selectivity between the vaporization of the uppermost organic layer of the substrate and the non vaporization of the conductive structure is driven by differences in ultra violet (UV) absorption of the materials, respectively, the ability of the materials to rapidly dissipate heat, and the vaporization temperatures of the materials, whereby the uppermost organic layer of the substrate typically absorbs more UV energy and is surrounded by low thermally conductive materials, leading to higher temperatures, which results in the vaporization of the upper most organic layer of the substrate and ejection of the capping layer thereupon.

Referring now to the FIGs, wherein like components are labeled with like numerals, exemplary fabrication steps and corresponding structure in accordance with embodiments of the present invention are shown, and will now be described in greater detail below. It should be noted that some of the FIGs depict cross section views. Furthermore, it should be noted that while this description may refer to components in the singular tense, more than one component may be depicted throughout the figures or a real world implementation of the embodiments of the present invention. The specific number of components depicted in the figures and the cross section orientation was chosen to best illustrate the various embodiments described herein.

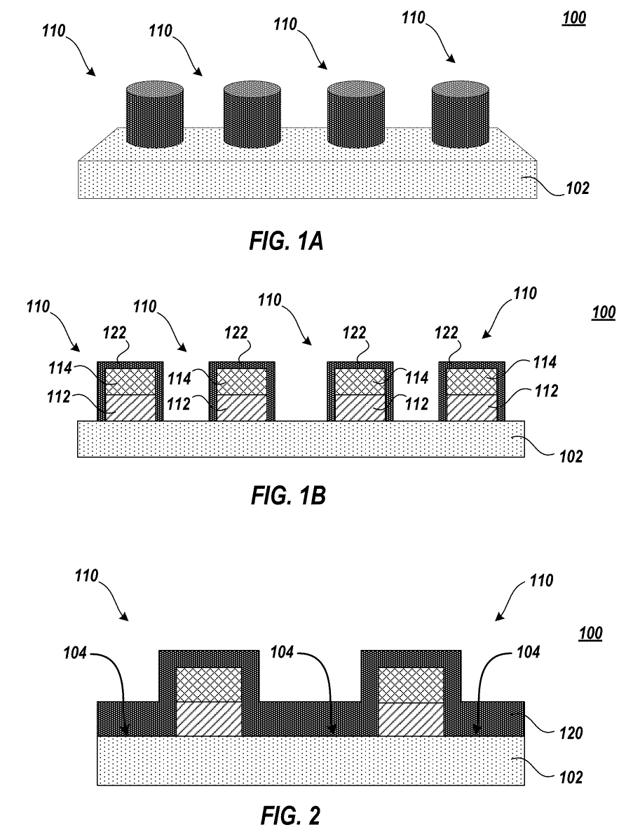

FIG. 1A and FIG. 1B depicts a semiconductor structure, such as a semiconductor wafer 100, in accordance with various embodiments of the present invention. Wafer 100 may include contact structures 110 formed upon a substrate 102. As is known in the art, wafer 100 may also include a plurality of chips (not shown) separated by kerfs (not shown). Each chip may include an active region wherein integrated circuit devices, microelectronic devices, etc. may be built using microfabrication process steps such as doping or ion implantation, etching, deposition of various materials, photolithographic patterning, electroplating, etc.

At least the uppermost surface of substrate 102 that which a capping layer 120 is formed upon is a polymer and may be an external layer of the wafer 100. For example, an upper surface of the substrate is covered by the formation of a dielectric or electrically insulating layer on a “working” or “active” surface of the substrate. This layer can comprise a polymer, such as a polyimide, or polybenzobisoxazole or “PBO,” e.g., HD8930, HD8820 or HD4100, all available from HD MicroSystems (http://hdmicrosystems.com), which can be deposited onto the substrate 102, for example, by a spinning operation.

A contact structure 110 is generally an electrically conductive connection structure used to transfer current and may be a C4 interconnect, a pad, pillar, etc. Contact structures 110 may be formed upon the substrate 100 via photoresist defined plating where a photoresist layer is formed upon the substrate, and subsequently patterned. The contact structure 110 is formed within the patterned photoresist and the photoresist is subsequently stripped from the substrate 102 utilizing a photoresist stripping solution. In one embodiment the contact structure 110 is formed utilizing a single electrically conductive material. For example, contact structure 110 may be a metal, such as copper. In other embodiments, the contact structure 110 may be formed utilizing multiple layered conductive materials. For example and as shown in FIG. 1B, contact structure 110 may include a base contact 112 and a re-flowable contact 114. Base contact 112 is an electrically conductive material, such as copper. Re-flowable contact 114 is a flowable electrically conductive material such as solder. In a particular embodiment, re-flowable contacts 114 may be C4s (controlled collapse chip connection) and base contact 112 may be a copper pillar, pad, etc. The contact structure 110 is generally electrically connected to integrated circuit devices or microelectronic devices within the active region of the chip. The contact structure 110 may be an external contact to allow for chip to package electrical communication.

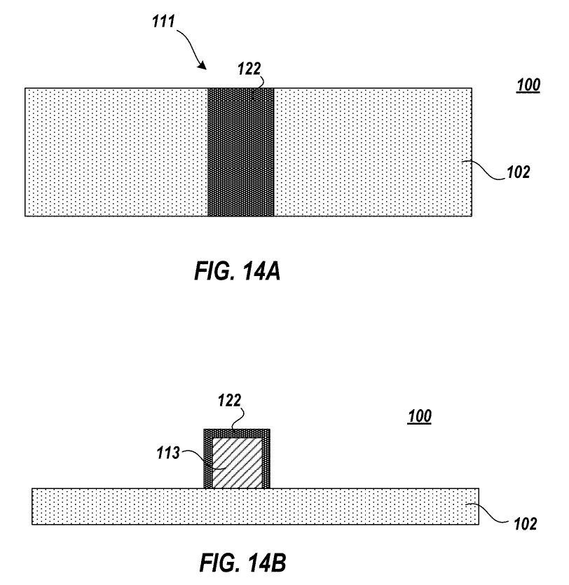

For clarity, though contact structures 110 are referenced throughout this detailed description, other conductive structures such as connection structures (e.g. wire lines, etc.) may be formed upon the substrate 102 by known fabrication techniques. For example, in FIG. 14A and in FIG. 14B a connection structure 111 is shown formed upon substrate 102. The cap 122 is formed thereupon by a selective maskless laser ejection technique as described herein. In an example, one end of the connection structure 111 may contact and be electrically connected to a first contact structure 110 and the proximate end of the connection structure 111 may electrically connected to a second contact structure 110. In another example, one end of the connection structure 111 may contact and be electrically connected to a first contact structure 110 and the proximate end of the connection structure 111 may contact and be electrically connected with another semiconductor device, such as the same contact structure 110, a transistor, via, etc. In other words, when appropriate, the term “connection structure” may take the place of the term “contact structure” throughout this document. The term “conductive structure” refers to either a contact structure or a connection structure.

For further clarity, wafer 100 shown in the FIGs may correspond to an intermediate fabrication stage of wafer 100. For example, the wafer 100 shown in FIG. 1A, FIG. 1B, FIG. 14A, or FIG. 14B may undergo further fabrication stages wherein semiconductor chips are diced from the wafer 100. The semiconductor chips may then undergo further fabrication or connection stages wherein the cap 122 may no longer be needed to protect the underlying conductive structure. At such stage the cap 122 may be removed from the semiconductor chip. In other words, the semiconductor structures of the FIGs may be an intermediary wafer 100 or semiconductor chip structure.

Subsequent to forming the contact structure 110, the contact structure 110 may be covered by a cap 122 to protect the contact structure 110 against moisture, dust, chemicals, and temperature extremes that, if uncoated (non-protected), could result in damage or failure of the contact structure 110. The cap 122 may be formed by utilizing a maskless selective removal technique to remove portions of a capping layer as is further described herein.

FIG. 2 depicts an initial fabrication process stage to form a cap 122 upon contact structure 110, according to embodiments of the invention. At the present stage of wafer 100 fabrication, a capping layer 120 is formed upon the substrate 102 covering contact structures 110. The capping layer 120 may be formed by known formation techniques such as deposition, brush coating, spray coating, dip coating, spin coating, etc. Deposition may include any now known or later developed techniques appropriate for the material to be deposited, including, but not limited to: chemical vapor deposition (CVD), liquid plasma CVD (LPCVD), Plasma-enhanced CVD (PECVD), semi-atmosphere CVD (SACVD), high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, physical vapor deposition (PVD), atomic level deposition (ALD), chemical oxidation, molecular beam epitaxy (MBE), etc. Region of wafer 100 where capping layer 120 contacts the substrate 102 directly are herein referred to as organic regions 104. Generally, organic region 104 is the exposed surface of substrate 102 between contact structures 110 prior to the formation capping layer 120.

Capping layer 120 may be made from any of several known semiconductor materials such as, for example, silicon nitride (Si₃N₄) or other similar semiconductor materials. Typically the capping layer 120 may be about, but is not limited to, several hundred nanometers thick. For example, the capping layer 120 may have a thickness ranging from 100 nm to about 1 micrometer thick. In one embodiment, the capping layer 120 is 500 nm thick.

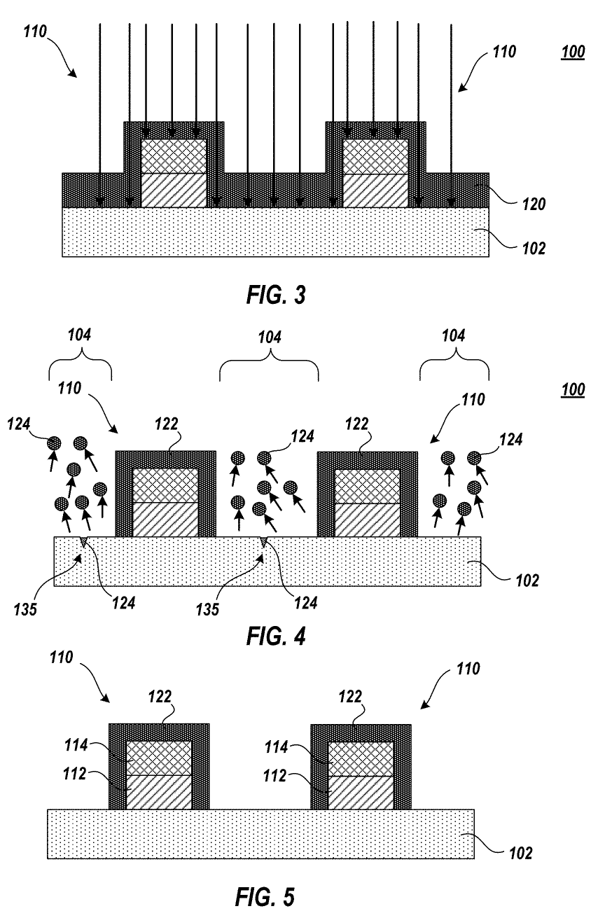

FIG. 3 depicts a subsequent fabrication process stage to form a cap 122 upon contact structure 110, according to embodiments of the invention. At the present stage of wafer 100 fabrication, a raster scan of an Eximer UV laser beam across wafer 100. The laser beam may be selectively raster scanned across the wafer 100 to selectively remove capping layer 120 material in organic region 104 of wafer 100.

An Excimer laser beam is impinged through the capping layer 120 onto substrate 102 to eject portions of the capping layer 120 while retaining the portion of the capping layer 120 covering the contact structure 110. The capping layer 120 is ejected at its interface with the substrate 102. The organic uppermost surface of the substrate 102 is vaporized by the laser resulting in a shockwave which ejects portions of the capping layer 120 while portions of the capping layer 120 covering the contact structure 110 are retained. The capping layer 120 over the contact structure 110 remains in place because the surface of the contact structure 110 is not vaporized by the laser. The selectivity between the vaporization of the uppermost layer of the substrate 102 and capping layer 120 is driven by differences in UV absorption, the ability of the substrate 102 and capping layer 120 to rapidly dissipate heat, and the vaporization temperatures of the substrate 102 and capping layer 120, whereby the uppermost layer of substrate 102 typically absorbs more UV energy and is surrounded by less thermally conductive materials, leading to higher temperatures, which result in the vaporization of the upper most surface of the substrate 102 thereby ejecting portions of the capping layer 120.

FIG. 4 depicts a subsequent fabrication process stage to form a cap 122 upon contact structure 110, according to embodiments of the invention. At the present stage of wafer 100 fabrication, the raster scan of an Eximer UV laser beam ejects capping layer 120 and vaporizes the uppermost surface of substrate 102 resulting in the capping layer 120 to be dislodged and ejected from the substrate 102 in organic region 104. The ejected capping layer 120 may be in the form of fine particulate 124. Though not shown in FIG. 4, the vaporization of the uppermost surface of substrate 102 may also result in a small amount of substrate 102 particulate to be expelled.

Subsequent to the removal of portions of capping layer 120, the upper surface of substrate 102 may include stich mark crevasses 135, or recesses within the substrate 102 formed by the laser. Residual capping layer 120 material may be included within the stich mark crevasses 135.

In regions of wafer 100 where capping layer 120 is in direct contact with more thermally conductive materials, such as contact structure 110 or more thermal stable materials (e.g. silicon), vaporization of such materials, structures, etc. does not occur and the capping layer 120 remains in place. For example, where capping layer 120 is contiguous with contact structure 110, the contact structure 110 thermally disperses the beam's heat energy and the capping layer 120 material is not ejected from the contact structure 110. As such, the capping layer 120 material upon the contact structure 110 is retained. The material of capping layer 120 that remains covering contact structure 110, subsequent to the ejection of capping layer 120 and the vaporization of the uppermost surface of substrate 102, forms cap 122, as is shown in FIG. 5. For clarity, the capping layer 120 is ejected from the surface of the substrate 102 by the shockwave caused by the vaporization of the uppermost surface of substrate 102 and not directly cut, burned, or ablated away.

The lasering technique for removing surplus capping layer 120 from substrate 102 using lasers effectively overcomes the above and other drawbacks of the conventional methods and offers enhanced process capabilities and lower manufacturing costs. The benefits enable production of semiconductor chips at lower costs and larger volumes by using a laser capping layer 120 ejection technique. The selective and maskless laser-based capping layer 120 removal technique can thus reduce the overall product manufacturing costs and improve process capability and yields.

Additionally, laser removal of the surplus capping layer 120 causes no undercutting of the contact structure 110, thereby enabling better reliability as circuitry features become smaller. The laser processing method is also more selective in its material removal, in that it removes the undesired surplus capping layer 120 without removing the desired thicker circuitry patterns (e.g., conductive contacts, RDL traces, etc.). The constraints on chip design and limits on the spacing that can be used between the conductive structures are eliminated using the laser process. Additionally, with the laser removal process, processing contaminates have no effect on the ejection process, thus eliminating the yield issues that affect the wet or dry etch processes. Moreover, the laser process requires no harsh chemicals to etch the wafer 100, thereby contributing to the green initiatives.

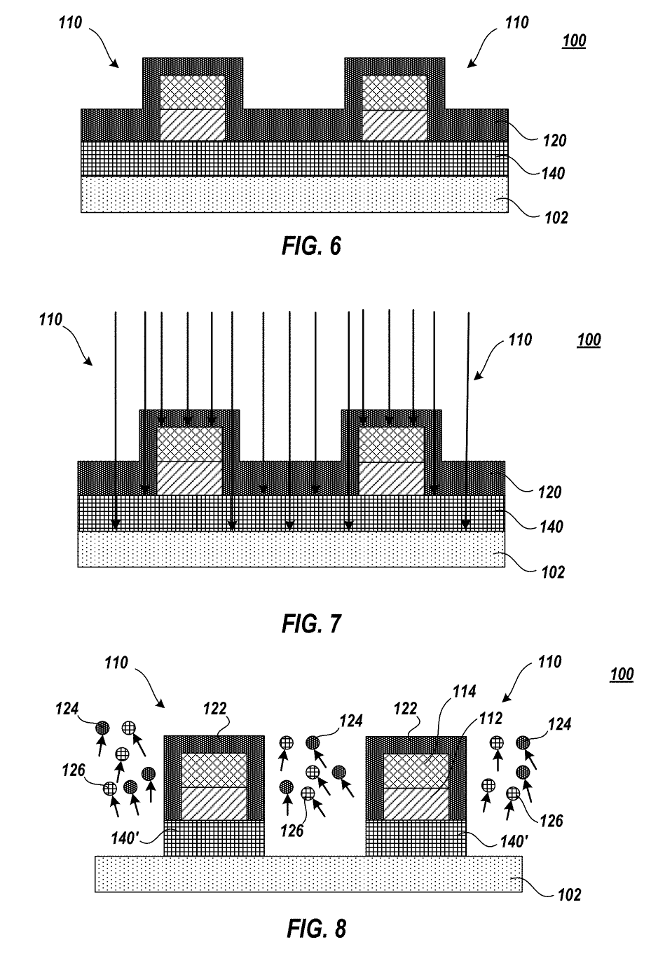

FIG. 6 depicts a fabrication process stage to form a cap upon a contact structure 110 utilizing a maskless selective removal technique to remove portions of capping layer 120. The cross section of the exemplary wafer 100 shown in FIG. 6 additionally includes a metal layer(s) 140 formed upon the substrate 102. The metal layer(s) 140 may be utilized in the formation of contact structures 110 in that a dual layer of sputtered metals is first formed upon the substrate 102, a photoresist layer (not shown) is subsequently formed upon the dual layer, and the photoresist layer is patterned. The contact structure 110 is electroplated within the patterned photoresist. Subsequent to plating, the photoresist is stripped from the semiconductor wafer utilizing a photoresist stripping solution. The bottom metal layer is typically used as both a barrier and an adhesion layer to the underlying substrate 102. The second upper layer is a current carrying or seed layer which is typically some form of copper or copper alloy utilized in the contact structure electroplating fabrication.

At the present stage of wafer 100 fabrication, a capping layer 120 is formed upon the metal layer 140 covering contact structures 110. The capping layer 120 may be formed by known formation techniques. Capping layer 120 may be made from any of several known semiconductor materials such as, for example, silicon nitride (Si₃N₄), or other similar semiconductor materials. Typically the capping layer 120 may be about, but is not limited to, several hundred nanometers thick. For example, the capping layer 120 may have a thickness ranging from 100 nm to about 1 micrometer thick. In one embodiment, the capping layer 120 is 500 nm thick.

FIG. 7 depicts a subsequent fabrication process stage to form a cap 122 upon contact structure 110, according to embodiments of the invention. At the present stage of wafer 100 fabrication, an Eximer UV laser beam is selectively scanned across wafer 100. An Excimer laser beam is impinged through the capping layer 120 onto underlying portions of wafer 100 and the uppermost surface of the substrate 102 which results in the impinging laser beam selectively ejecting the capping layer 120 and the metal layer 140. A portion of the laser beam energy passes through the capping layer 120 and is absorbed by the metal layer 140 and the uppermost surface of the substrate 102. The generated heat within and nearby the metal layer 140 is not quickly diffused away as the metal layer 140 is located between thermally insulative materials. The resulting heating of metal layer 140 vaporizes the upper most portion of the substrate 102 resulting in a shockwave which ejects portions of the metal layer 140 and portions of the capping layer 120 while other portions of the metal layer 140 and other portions of the capping layer 120 that are contiguous with the contact structure 110 are retained. The capping layer 120 over the contact structure 110 and the metal layer 140 under the contact structure 110 remains in place because the surface of contact structure 110 is not vaporized by the laser. The ejected capping layer 120 may be in the form of fine particulate 124 and the ejected metal layer 140 may be in the form of fine particulate 126, as is shown in FIG. 8.

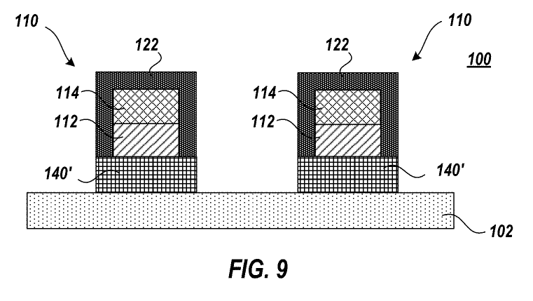

In regions of wafer 100 where capping layer 120 is in direct contact with more thermally conductive materials, such as contact structure 110 or more thermal stable materials (e.g. silicon), vaporization of such materials, structures, etc. does not occur and the capping layer 120 and metal layer 140 remains in place. For example, where capping layer 120 and metal layer 140 is contiguous with contact structure 110, the contact structure 110 thermally disperses the beam's heat energy and the capping layer 120 material and metal layer 140 material are not heated to the requisite temperature to be ejected from the contact structure 110. As such, the capping layer 120 material upon the contact structure 110 and the metal layer 140 material under the contact structure 110 are retained. The material of capping layer 120 that remains covering contact structure 110, subsequent to the ejection of capping layer 120, forms cap 122, and the material of metal layer 140 that remains under contact structure 110, subsequent to the ejection of metal layer 140, forms metal portion 140′ as is shown in FIG. 9.

The lasering technique for removing surplus capping layer 120 and metal layer 140 materials from substrate 102 using lasers effectively overcomes the above and other drawbacks of the conventional methods and offers enhanced process capabilities and lower manufacturing costs. The benefits enable production of semiconductor chips at lower costs and larger volumes by using a laser ejection technique. The selective and maskless laser-based ejection technique can thus reduce the overall product manufacturing costs and improve process capability and yields.

Additionally, laser removal of the surplus capping layer 120 and metal layer 140 materials causes no undercutting of the contact structure 110, thereby enabling better reliability as circuitry features become smaller. The laser processing method is also more selective in its material removal, in that it removes the undesired surplus metal layer 140 material without removing the desired thicker circuitry patterns (e.g., conductive contacts, RDL traces, etc.). The constraints on chip design and limits on the spacing that can be used between the metal structures are eliminated using the laser process. Additionally, with the laser removal process, processing contaminates have no effect on the ejection process, thus eliminating the yield issues that affect the wet or dry etch processes. Moreover, the laser process requires no harsh chemicals to etch the wafer 100, thereby contributing to the green initiatives.

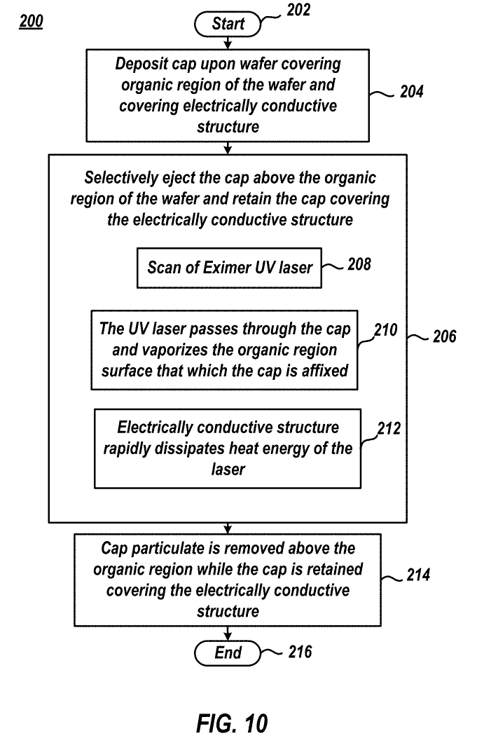

FIG. 10 depicts an exemplary semiconductor device fabrication flow method 200, according to embodiments of the invention. Method 200 may be utilized to fabricate a wafer 100 that includes contact structures 110 or connection structures 111 covered by caps 122 formed utilizing a maskless selective removal technique to remove portions of capping layer 120 from substrate 102 of wafer 100.

Method 200 begins at block 202 and continues by depositing a capping layer 120 upon substrate 102 of the wafer 100 covering organic region 104 of wafer 100 and covering an electrically conductive structure, such as a contact structure 110 or connection structure 111 (block 204). For example, capping layer 120 may be deposited upon substrate 102 by CVD, or the like. Method 200 may continue by selectively ejecting portions of the capping layer 120 above organic region 104 of wafer 100 and retaining portions of the capping layer covering the electrically conductive structure to form cap 122 (block 206).

An Excimer laser beam may be scanned across the wafer 100 and impinged through the capping layer 120 onto underlying portions of wafer 100 (block 208). A laser beam may be sized to best match the substrate 102 size and the fluence required (e.g., 50 mJ-2.5 J, etc.) at the substrate 102 to selectively eject capping layer 120. As the substrate 102 is moved at some predetermined velocity, a portion of the substrate 102 is exposed to the UV laser light, for example, at wavelengths of 308 nm or 248 nm. Eventually, all of the substrate 102 where selective removal of the capping layer is desired will be exposed to the laser beam; however, only capping layer 120 is largely removed when the proper fluence is applied.

The size of the laser beam used is affected by several factors, including, for example, the size of the substrate 102, the fluence required at the substrate 102 for effective capping layer 120 ejection, available power, and the like. The laser beam may be continuously scanned across the surface of the substrate 102 by, for example, moving the substrate 102 and X-Y translation stage across the laser beam, with the laser apparatus pulsing at a given frequency. In this fashion, the laser beam may be stepped or rastered across the substrate 102 until the entire or some portion of the substrate 102 has been illuminated. Thus, after one corresponding section of the capping layer 120 has been ejected, a new section of the substrate 102 that has not been subjected to the laser is moved under the laser beam, where the laser apparatus is again pulsed and the capping layer 120 in the corresponding area is ejected. This “step, pulse, and repeat” process can be implemented at very high rates of speed, typically limited only by the speed of travel of the substrate 102 relative to the laser apparatus or vice-versa.

The UV laser passes through the capping layer 120 and vaporizes the uppermost organic layer of the substrate surface that which the capping layer 120 is affixed (block 210). The capping layer 120 is ejected at its interface with the substrate 102 by the laser vaporizing by the uppermost organic layer resulting in a shockwave which ejects the capping layer 120.

Method 200 continues by the electrically conductive structure rapidly dissipating heat energy of the laser (block 212) causing the capping layer 120 upon the conductive structure remains in place because the surface of the conductive structure is not vaporized by the laser.

Method 200 may continue by removing capping layer 120 particulate 124 above organic region 104 while retaining cap 122 covering the electrically conductive structure (block 214). For example, the scan of the Eximer UV laser beam ejects capping layer 120 and vaporizes the uppermost surface of substrate 102 resulting in the capping layer 120 to be dislodged and ejected as particulate 124 from the substrate 102 in organic region 104. The capping layer 120 material covering the electrically conductive structure is retained because the electrically conductive structure dissipates heat resulting in local temperatures at the electrically conductive structure capping layer 120 interface to be lower than the capping layer 120 vaporization temperature. The cap 122 covering the electrically conductive structure is not ejected but, rather, retained because, in this region, capping layer 120 is in direct contact with more thermally conductive materials (i.e. the electrically conductive structure) that dissipates heat energy of the laser beam. Method 200 ends at block 216.

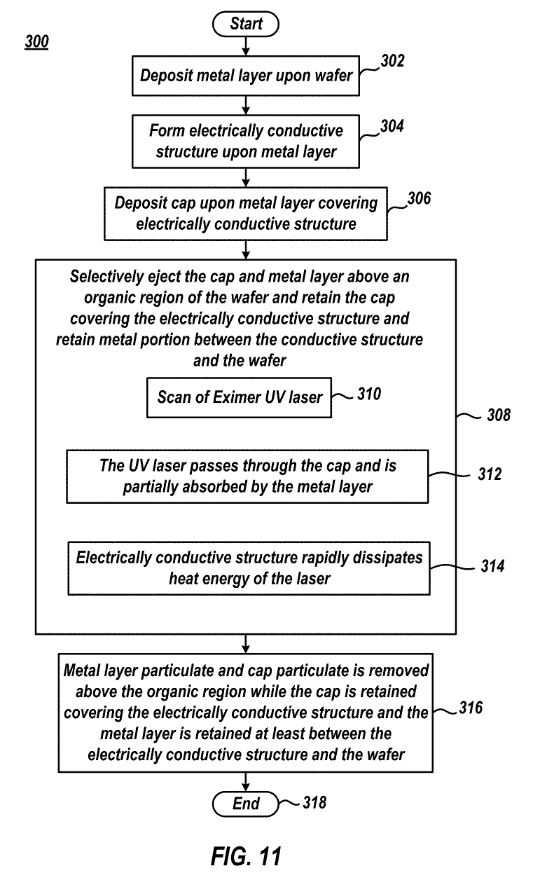

FIG. 11 depicts an exemplary semiconductor device fabrication flow method 300, according to embodiments of the invention. Method 300 may be utilized to fabricate a wafer 100 that includes contact structures 110 or connection structures 111 covered by caps 122 formed utilizing a maskless selective removal technique to remove portions of a capping layer 120 and metal layer 140 from substrate 102 of wafer 100.

Method 300 begins at block 302 and continues with depositing a metal layer(s) 140 upon substrate 102 of wafer 100 (block 302). The metal layer 140 may be utilized in the formation of conductive structures, such as contact structures 110 or connection structures 111. For example, a dual layer of sputtered metals is formed upon the substrate 102.

Method 300 may continue by forming an electrically conductive structure upon metal layer 140 (block 304). For example, a photoresist layer may be formed upon the metal layer 140, and the photoresist layer is patterned. A electrically conductive structure may be electroplated within the patterned photoresist. Subsequent to plating, the photoresist is stripped from the semiconductor wafer utilizing a photoresist stripping solution. The bottom portion of the metal layer is typically used as both a barrier and an adhesion layer to the substrate 102 and the upper portion of the metal layer is a current carrying or seed layer which is typically some form of copper or copper alloy utilized in the contact structure 110 electroplating fabrication.

Method 300 may continue by forming a capping layer 120 upon the metal layer 140 covering the electrically conductive structure (block 306). For example, the capping layer 120 may be deposited, etc. upon the upper surface of the metal layer such that the capping layer 120 covers the metal layer 140 and covers the electrically conductive structure.

Method 308 may continue by selectively ejecting portions of the capping layer 120 and portions of the metal layer 140 above an organic region 104 of the wafer 100 and retaining cap 122 covering the electrically conductive structure and retaining a metal portion 140′ between the electrically conductive structure and the substrate 102 (block 308).

An Excimer laser beam may be scanned across the wafer 100 and impinged through the capping layer 120 onto the metal layer 140 (block 310). A rectangular or square shaped laser beam may be sized to best match the substrate 102 size and the fluence required to eject capping layer 120 and the metal layer 140. As the substrate 102 is moved at some predetermined velocity, a portion of the metal layer 140 is exposed to the UV laser light. Eventually, all or a portion of the substrate 102 will be exposed to the laser beam.

The size of the laser beam used is affected by several factors, including, for example, the size of the substrate 102, the fluence required for effective capping layer 120 and metal layer 140 ejection, available power, and the like. The laser beam may be continuously scanned across the wafer 100, for example, moving the wafer 100 and X-Y translation stage across the laser beam, with the laser apparatus pulsing at a given frequency. In this fashion, the laser beam may be stepped or rastered across the wafer 100 until the entire area has been illuminated. Thus, after one corresponding section of the ejected capping layer 120 and metal layer 140 has been removed, a new section of the substrate 102 that has not been processed is moved under the laser beam, where the laser apparatus is again pulsed and the capping layer 120 and metal layer 140 in the corresponding area is ejected. This “step, pulse, and repeat” process can be implemented at very high rates of speed, typically limited only by the speed of travel of the wafer 100 relative to the laser apparatus or vice-versa.

A portion of the laser beam energy passes through the capping layer 120 and is absorbed by the metal layer 140 (block 312). The generated heat within the metal layer 140 is not quickly diffused away as the metal layer 140 is located between thermally insulative materials (i.e. the substrate 102 and the capping layer 120). The resulting heating of metal layer 140 vaporizes the upper most portion of the substrate 102 resulting in a shockwave which ejects portions of the metal layer 140 and portions of the capping layer 120 while other portions of the metal layer 140 and other portions of the capping layer 120 that are contiguous with the contact structure 110 are retained.

In regions where capping layer 120 and metal layer 140 is in direct contact with conductive structure vaporization of capping layer 120 and metal layer 140 materials does not occur and the capping layer 120 and metal layer 140 remains in place. For example, where capping layer 120 and metal layer 140 is contiguous with contact structure 110, the contact structure 110 thermally disperses the beam's heat energy and the capping layer 120 material and metal layer 140 material are not heated to the requisite temperature to be ejected from the contact structure 110 (block 314). As such, the capping layer 120 material upon the contact structure 110 and the metal layer 140 material under the contact structure 110 are retained.

Method 300 may continue with removing metal layer 140 particulate 126 and capping layer 120 particulate 124 generally above the organic region 104 of wafer 100 between electrically conductive structures while the cap 122 that covers the electrically conductive structure is retained and while the metal portion 140′ at least between each of the electrically conductive structures and the substrate 102 is retained (block 316). Method 300 ends at block 318.

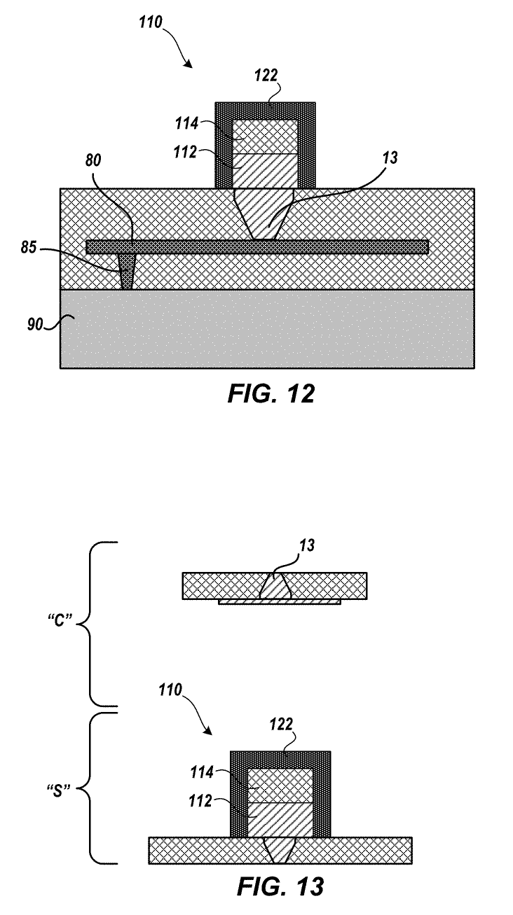

FIG. 12 shows an exemplary semiconductor structure implementing an embodiment of the present invention. Although FIG. 12 shows a single contact structure 110, it should be understood by those of skill in the art that a plurality of contacts can be formed on the surface of the structure using the fabrication processes above. In the example of FIG. 12, one or more dielectric layers are formed upon a semiconductor substrate. The substrate may be, for example, silicon or other known substrates for semiconductor devices. The substrate includes an upper most organic layer. A metal interconnect(s) 85 and connecting metal line(s) 80 may be formed in the one or more dielectric layers using conventional damascene and deposition processes. A inter dielectric contact 13 (e.g. via, etc.) is formed in the dielectric layers 8. Contact structure 110 is formed generally upon inter dielectric contact 13. Subsequently a cap 122 is formed upon the contact structure 110 utilizing a maskless selective removal laser technique by selectively removing portions of capping layer 120 (not shown) above the organic layer of the substrate between contact structures 110.

In embodiments of the invention, the contact structure 110 and cap 122 may be comprised within a chip (e.g. see FIG. 12, etc.) or within a package or carrier (e.g. see FIG. 13, etc.). By way of example, FIG. 11 shows a chip “C” and a package or carrier “S”.

The exemplary methods and techniques described herein may be used in the fabrication of integrated circuit chips. The resulting integrated circuit chips can be distributed by the fabricator in raw wafer form (i.e., as a single wafer that has multiple unpackaged chips), as a bare die, or in a packaged form. In the latter case, the chip is mounted in a single chip package (e.g., a carrier, with leads that are affixed to a motherboard or other higher level carrier) or in a multichip package (e.g., a carrier that has either or both surface interconnections or buried interconnections). The chip is then integrated with other chips, discrete circuit elements and/or other signal processing devices as part of either (a) an intermediate product, such as a motherboard, or (b) an end product. The end product can be any product that includes integrated circuit chips, ranging from toys and other low-end applications to advanced computer products having numerous components, such as a display, a keyboard or other input device and/or a central processor, as non-limiting examples.

References herein to terms such as “vertical”, “horizontal”, etc. are made by way of example, and not by way of limitation, to establish a frame of reference. The term “horizontal” as used herein is defined as a plane parallel to the conventional plane or surface of a wafer substrate, regardless of the actual spatial orientation of the substrate 102. The term “vertical” refers to a direction perpendicular to the horizontal, as just defined. Terms, such as “on”, “above”, “below”, “side” (as in “sidewall”), “higher”, “lower”, “upper”, “over”, “beneath” and “under”, are defined with respect to the horizontal plane. It is understood that various other frames of reference may be employed for describing the present invention without departing from the spirit and scope of the present invention.

What is claimed is:

1. A method to form a cap upon a semiconductor chip to package interconnect contact structure comprising:
forming a contact structure upon an uppermost organic layer of a semiconductor substrate;
forming a capping layer upon the uppermost organic layer covering the contact structure, and;
directing a laser beam to eject portions of the capping layer from the uppermost organic layer and form a cap by retaining the capping layer covering the electrically conductive structure.

2. The method of claim 1, wherein portions of the capping layer are ejected from the uppermost organic layer by a shockwave as a result of the laser beam vaporizing the uppermost organic layer of the semiconductor substrate.

3. The method of claim 1, wherein the capping layer is formed from silicon nitride.

4. The method of claim 1, wherein the capping layer covering the contact structure is retained by the contact structure dissipating heat from the laser that would otherwise vaporize the uppermost organic layer of the semiconductor substrate.

5. The method of claim 1, further comprising:
removing particulate of the ejected portions of the capping layer.

6. The method of claim 1, wherein the contact structure is a contact pad.

7. The method of claim 1, wherein the semiconductor substrate is semiconductor substrate of carrier.

8. The method of claim 1, wherein the semiconductor substrate is semiconductor substrate of a semiconductor chip.

9. The method of claim 1, wherein the semiconductor substrate is semiconductor substrate of a wafer.
